(19) United States
(12) Patent Application Publication
(10) Pub. No.: US 2003/0031072 A1
(43) Pub. Date: Feb. 13, 2003

(54) Memory with row-wise write and column-wise read

(76) Inventors: Eliel Louzoun, Jerusalem (IL); Dima A. Hammad, Jerusalem (IL)

Correspondence Address: Eitan, Pearl, Latzer & Cohen-Zedek, One Crystal Park, Suite 210, 2011 Crystal Drive, Arlington, VA, 22202-3709, US

(21) Appl. No.: 09/923,421

(22) Filed: Aug. 8, 2001

(51) Int. Cl. G11C 7/10

(52) U.S. Cl. 365/220

(57) ABSTRACT

A memory is organized into both rows and columns, and includes a write access circuit connected to the memory cells in a row-wise manner and a read access circuit connected to the memory cells in column-wise manner.

### FIELD OF THE INVENTION

The present invention relates to a memory; more specifically to a random access memory (RAM) where data may be written to the RAM in a row-wise manner and data may be read from the RAM in a column-wise manner.

### BACKGROUND OF THE INVENTION

Certain data processing applications are both memory intensive, requiring multiple read and write cycles to and from a memory, and require the interleaving of data. For example, Forward Error Correction (FEC) schemes are used to increase a transceiver's error correction capabilities Data is interleaved, transmitted, received, and de-interleaved. De-interleaving involves interleaving previously interleaved data, and thus is effectively the same process as interleaving. Other data processing tasks may use interleaving, and may use techniques requiring data to be written in one dimension, such as a row, and read in another dimension, such as a column.

In one method of interleaving data, data is written row-wise into rows having a certain number of columns, and then is read column-wise. For example, FIG. 1 is an example of a table illustrating the organization of bits during interleaving. Table 500 includes m*n bits 502 arranged in m rows 510 and n columns 520. The data to be interleaved is written into the table 500 as bits 502 row by row. Each bit 502 is then read from the table 500 column by column. In a digital data processing system a memory such as a RAM is used to store such data while interleaving.

A typical known memory, such as a RAM, organizes data as bits or bytes arranged in sets of rows. Such a memory allows access to data in one manner only—for example, by reading and writing blocks of data, each block comprising an entire row, or by reading and writing blocks of data within a row. A series of bits may be efficiently written into a memory having such a structure in a row-wise manner, as the memory allows access to data in units of rows (or as units of blocks forming these rows). A single write operation may suffice to fill an entire row. To read the same data in a column-wise manner requires sequentially accessing each row; one bit or unit of data is read for each row. For each column desired to be read, the number of sequential read operations or read cycles is equal to the number of rows Thus, much more time and power is consumed during the read operation than during the write operation.

Such memories typically include address decoding circuitry for access to the proper portion of the memory for reading or writing. An address decoder may, for example, accept an address of a bit or byte to be accessed. The address decoder determines in which row the byte is stored, and signals that row for a read or write operation. Certain “dual port” memories include two address decoders. Such memories may allow simultaneous read and write operations; however, such memories allow simultaneous read and write operations in the same dimension only; i.e., reading to and writing from the memory in a row-wise manner only.

A sequence in a memory or a table of data is termed a “row” or a “column” based on the visual orientation when presented to a human being. Since, when stored in a memory device, “rows” and “columns” are arbitrary designations, when used herein with respect to a specific device or applications the terms row and column may be transposed. For example, in the table of FIG. 1, if the table 500 is rotated 90 degrees, each row 510 may be termed a column, and each column 520 may be termed a row. While a row may also be termed a line, when used herein, the term line is restricted to its common usage as a device (such as a wire or a layer of electrically transmitting material) which transmits signals. However, using another sense of the word “line,” a set of data written row-wise can also be said to be written line-wise.

Certain data processing tasks that require interleaving, such as FEC, require data to be read in a dimension opposite the dimension it was written. Conventional memory devices perform this task inefficiently.

Thus, a need exists for a memory device that allows quicker access to data, in particular data organized and accessed both by row and by column.

### SUMMARY OF THE INVENTION

One embodiment of the present invention provides a memory which is organized into both rows and columns, and which includes a write access circuit connected to the memory cells in a row-wise manner and a read access circuit connected to the memory cells in column-wise manner.

### BRIEF DESCRIPTION OF THE DRAWINGS

The present invention will be understood and appreciated more fully from the following detailed description taken in conjunction with the drawings in which:

FIG. 1 is an example of a table illustrating the organization of bits during interleaving;

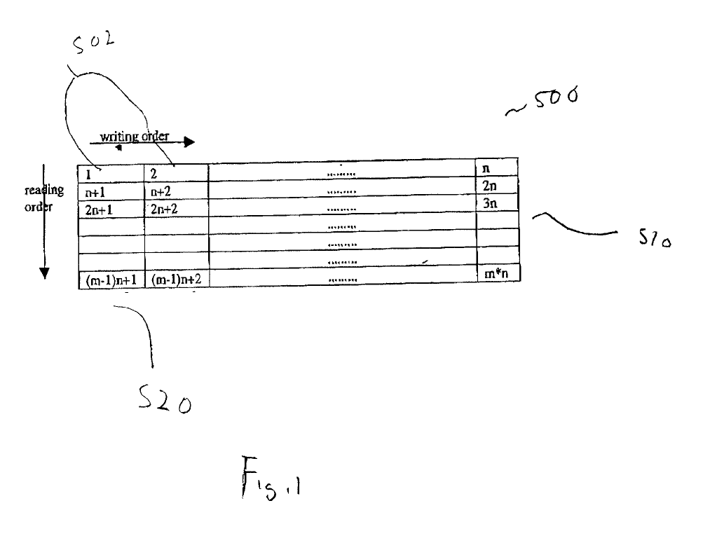

FIG. 2 is a schematic diagram of a memory device according to an embodiment of the present invention; and

FIG. 3 is a block diagram depicting a data processing device including a memory according to an embodiment of the present invention.

### DETAILED DESCRIPTION OF THE INVENTION

In the following description, various aspects of the present invention will be described For purposes of explanation, specific configurations and details are set forth in order to provide a thorough understanding of the present invention. However, it will also be apparent to one skilled in the art that the present invention may be practiced without the specific details presented herein. Furthermore, well known features may be omitted or simplified in order not to obscure the present invention.

An exemplary embodiment of the present invention provides for a memory device which may accept data for write operations in a row-wise manner and which may output data in read operations in a column-wise manner. In such a manner, data may quickly be written in a row-wise manner and quickly read in a column-wise manner. Thus the present invention is suited to applications which require interleaving of data and thus which require quick access of data in both a row and column-wise manner.

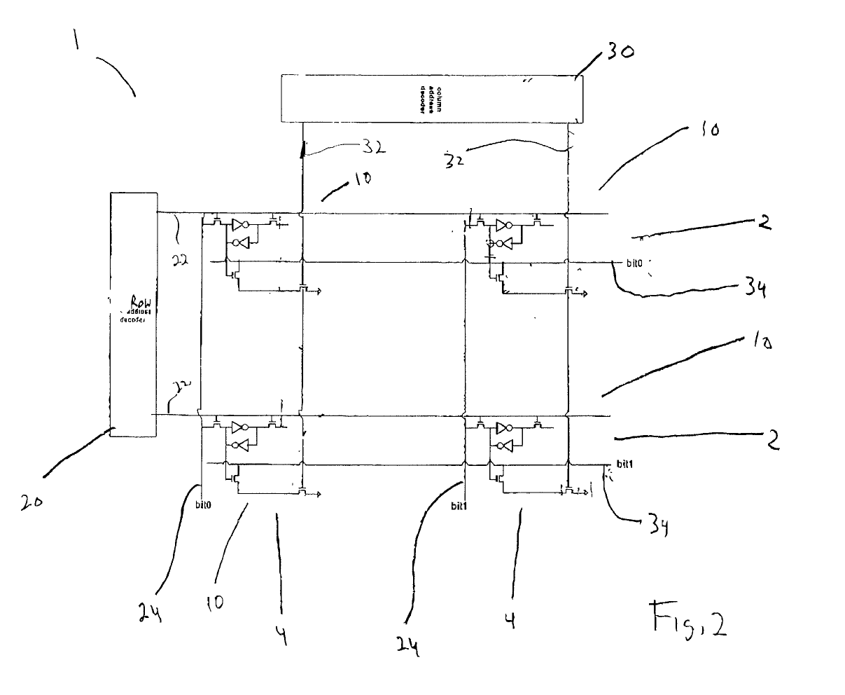

FIG. 2 is a schematic diagram of a memory device according to an embodiment of the present invention. Referring to FIG. 2, memory 1 includes a plurality of memory units 10, each storing one bit of data. The memory units 10 are divided into rows 2 and columns 4. Memory 1 includes row address decoder 20, for accessing individual rows 2 of data, column address decoder 30, for accessing individual columns 4 of data, a set of write lines 24, for writing data to the memory units 10, and a set of read lines 34, for reading data to the memory units 10. Each write line 24 is connected to a set of memory units 10 comprising a row 2, and each read line 34 is connected to a set of memory units 10 comprising a column 4. In operation, data is written to memory units 10 via the write lines 24, and data is read from the memory units 10 via the read lines 34.

Each memory unit 10 is preferably a bi-stable SRAM memory cell of known CMOS construction, storing one bit of data and including components such as transistors and inverters. In alternate embodiments other types of memory units having other construction may be used; such memory units are well known in the art. For example, a memory unit may store more than one bit of data. Preferably, each of the row address decoder 20 and column address decoder 30 are address decoders of known construction. In alternate embodiments the write access circuit and read access circuit used to read and write data to and from memory cells may be of different construction and may include other functions; such access circuits are well known in the art. In an exemplary embodiment the memory unit 1 fits on one chip, and further may be combined on one chip with other components such as a processor.

Extending from the row address decoder 20 is a set of row address lines 22, for selecting individual rows 2 of memory units 10 for data writing; each row address line 22 is connected to a set of memory units 10 comprising a row 2.

Extending from the column address decoder 30 is a set of column address lines 32, for selecting individual columns 4 of memory units 10 for data reading; each column address line 32 is connected to a set of memory units 10 comprising a column 4.

The inputs to the row address decoder 20 and column address decoder 32 may be varied, and may be presented to other units in a computing system in different manners. For example, the memory 1 may have as interfaces to other units a set of row address lines and a set of column address lines, and in addition control lines such as a read/write command line and a set of data lines. The memory 1 may be placed in a package which provides a row-wise write/column-wise read memory, or may be integrated into a device to provide a row-wise write/column-wise read memory. The write lines 24 and read lines 34 may be connected, directly or indirectly, to the interface or output for such a row-wise write/column-wise read memory. Other methods of interfacing the memory 1 with other units may be used; such interfaces are well known in the art.

In operation, data is written to the memory 1 one row at a time. An address signal is sent to the row address decoder 20 via known methods, and the row address 20 decoder decodes the signal, sending a write signal to the one of the row address lines 22 corresponding to the row 2 addressed by the address signal. An address signal may be, for example, a set of bits corresponding to an address which may be decoded into an address corresponding to on of the row address lines 22. Methods of converting memory address signals into signals on memory address lines are known. At the same time, the data to be written to the memory units 10 comprising the selected row 2 appears on the write lines 24, and the memory units 10 comprising the selected row accept the data.

To read a column, an address signal is sent to the column address decoder 30 via known methods, and the column address 30 decoder decodes the signal, sending a read signal to the one of the column address lines 32 corresponding to the column 4 addressed by the address signal. The data to be read from the memory units 10 comprising the selected column 4 appears on the read lines 44, and the interface (not shown) provides the data to a unit accepting the data (not shown).

Preferably, during operation, when a row 2 is written, the entire row 2 is written and when a column 4 is read, the entire column 4 is read. In alternate embodiments, data may be written or read in blocks such as bytes which may be of a smaller dimension than a row or column. Further, since a “row” and a “column” is an arbitrary designation, a memory according to an embodiment of the present invention may be write enabled by column and read enabled by row. In alternate embodiments, each of the dimensions need not be restricted to only reading or only writing; for example, the rows, columns, or both may be both read and write enabled.

While, as depicted, memory 1 is a two by two square, the memory according to the present invention may include any dimensions and need not be square. For example, the rows may be of different dimension than the columns. Preferably, the dimensions of the memory 1 are chosen based on the application using the memory 1. Furthermore, the memory cells need not be divided into “rows” and “columns”; the memory units may be divided into any dimensions, where different sets of memory units are placed in each dimension.

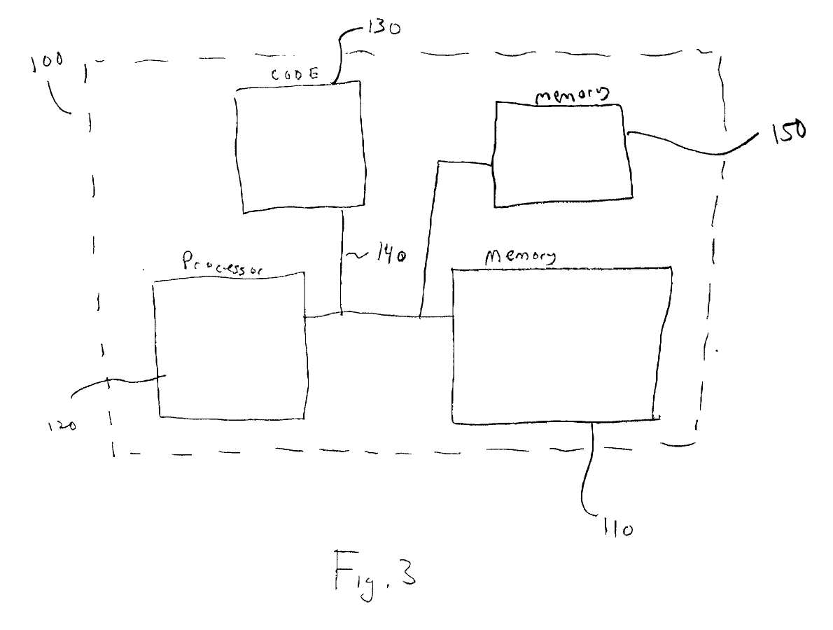

Various applications may be used with a memory according to embodiments of the present invention. FIG. 3 is a block diagram depicting a data processing device including a memory according to an embodiment of the present invention. Such a data processing device 100 (such as a personal computer or a specialized card or subsystem in a computer) which performs, for example, FEC, may include a memory 110 according to an embodiment of the present invention, a processor 120 (such as a microprocessor), a random access memory 150 (such as an SRAM or DRAM) and a code memory 130 (such as an RAM or ROM) storing instructions. The components may be connected by a data bus 140, which may be a series of data busses. Other known components (not shown) may be included, such as a power supply, an input output controller.

To perform a data interleaving application, the processor 100, following instructions contained in code memory 130, may accept a block of data. The data may be written to the memory 110 in a row-wise fashion, row by row. The data may be then read from the memory 110 in a column-wise fashion, column by column, processed by the processor 120, and transmitted. In one embodiment, each of the components of the data processing device 100 are placed on one chip. Other applications and systems may use a memory according to the present invention.

It will be appreciated by persons skilled in the art that the present invention is not limited by what has been particularly shown and described hereinabove. Rather the scope of the invention is defined by the claims that follow:

What is claimed is:

1. A memory comprising:
a plurality of memory units, the plurality of memory units being organized into rows, each row including a subset of memory units, the plurality of memory units also being organized into columns, each column including at least one memory unit from each of the rows;
a write access circuit connected to sets of the memory units in a row-wise manner and
a read access circuit connected to sets of the memory units in column-wise manner.

2. The memory of claim 1, wherein the read access circuit allows all the memory units from a selected one of the columns to be read simultaneously.

3. The memory of claim 1, wherein the write access circuit allows all the memory units from a selected one of the rows to be written to simultaneously.

4. The memory of claim 1, wherein:
the write access circuit includes at least an address decoder; and
the read access circuit includes at least an address decoder.

5. The memory of claim 1, wherein the write access circuit includes read access circuitry.

6. The memory of claim 1, wherein the read access circuit includes write access circuitry.

7. The memory of claim 1, wherein:
the write access circuit includes at least a set of write address lines, each write address line attached to a set of memory units; and
the read access circuit includes at least a set of read address lines, each read address line attached to a set of memory units.

8. The memory of claim 7, wherein:
in each row, each memory unit in that row is attached to a different read address line; and
in each row, each memory unit in that row is attached to the same write address line.

9. The memory of claim 1, wherein the memory includes a random access memory.

10. The memory of claim 1, wherein each memory unit stores one bit.

11. A memory comprising:
a plurality of memory units, the plurality of memory units being organized into rows, each row including a subset of memory units, the plurality of memory units also being organized into columns, each column including at least one memory unit from each of the rows;
a write access circuit connected to sets of the memory units in a row-wise manner, wherein the write access circuit allows all the memory units from a selected one of the rows to be written to simultaneously; and
a read access circuit connected to sets of the memory units in column-wise manner.

12. A memory comprising:
a plurality of memory units, the plurality of memory units being organized into rows, each row including a subset of memory units, the plurality of memory units also being organized into columns, each column including at least one memory unit from each of the rows;
a write access circuit including at least an address decoder and connected to sets of the memory units in a row-wise manner; and
a read access circuit including at least an address decoder and connected to sets of the memory units in column-wise manner.

13. A memory comprising:
a plurality of memory units;
a write access circuit, the write access circuit including a set of write control lines, each write control line being connected to a row-wise set of memory units; and
a read access circuit, the read access circuit including a set of write control lines, each read control line being connected to a column-wise set of memory units, each column-wise set of memory units including one memory unit from each row-wise set of memory units.

14. A memory comprising:
a plurality of memory units, the plurality of memory units being organized into rows, each row including a subset of memory units, the plurality of memory units also being organized into columns, each column including at least one memory unit from each of the rows;
a write access circuit connected to sets of the memory units in a row-wise manner, the write access circuit including at least a set of write address lines, each write address line attached to a set of memory units; and
a read access circuit connected to sets of the memory units in column-wise manner, the read access circuit including at least a set of read address lines, each read address line attached to a set of memory units.

15. A memory comprising:
a plurality of memory units, the plurality of memory units being organized into rows and columns;
a write access circuit connected to sets of the memory units in a row-wise manner, the write access circuit including at least an address decoder and a set of write address lines, each write address line attached to a set of memory units; and
a read access circuit connected to sets of the memory units in column-wise manner, the read access circuit including at least a an address decoder and a set of read address lines, each read address line attached to a set of memory units.

16. A memory comprising:
a plurality of memory units, the plurality of memory units being organized into a first set of sets of memory units according to a first dimension and a second set of sets of memory units according to a second dimension;
a write access circuit allowing a set of data to be written to a set of memory units in a selected set from the first set of sets; and
a read access circuit allowing a set of data to be read from a set of memory units in a selected set from the set of second sets.

17. The memory according to claim 16, wherein the first dimension corresponds to rows and the second dimension corresponds to columns.

18. The memory of claim 16, wherein the write access circuit allows all the memory units from a selected set from the first set of sets to be written to simultaneously.

19. The memory of claim 16, wherein:
the write access circuit includes at least an address decoder; and
the read access circuit includes at least an address decoder.

20. The memory of claim 16, wherein:
the write access circuit includes at least a set of write address lines, each write address line being attached to a set of memory units; and
the read access circuit includes at least a set of read address lines, each read address line being attached to a set of memory units.

21. A memory comprising:
a plurality of memory units, the plurality of memory units being organized into a first set of sets of memory units according to a rows and a second set of sets of memory units according to columns;
a write access circuit allowing a set of data to be written to a set of memory units in a selected set from the first set of sets; and
a read access circuit allowing a set of data to be read from a set of memory units in a selected set from the set of second sets.

22. A memory comprising:
a plurality of memory units;
a write access means, the write access means including a set of write control lines, each write control line being connected to a row-wise set of memory units; and
a read access means, the read access means including a set of write control lines, each read control line being connected to a column-wise set of memory units, each column-wise set of memory units including one memory unit from each row-wise set of memory units.

23. A memory comprising:
a plurality of memory units, the plurality of memory units being organized into a first set of sets of memory units according to a first dimension and a second set of sets of memory units according to a second dimension;
a write access circuit including at least an address decoder and allowing a set of data to be written to a set of memory units in a selected set from the first set of sets; and
a read access circuit including at least an address decoder and allowing a set of data to be read from a set of memory units in a selected set from the set of second sets.

24. A memory comprising:
a plurality of memory units, the plurality of memory units being organized into a first set of sets of memory units according to a first dimension and a second set of sets of memory units according to a second dimension;
a write access circuit including at least a set of write address lines, each write address line being attached to a set of memory units; and
a read access circuit including at least a set of read address lines, each read address line being attached to a set of memory units.

25. A memory comprising:
a plurality of memory units means, the plurality of memory unit means being organized into rows, the plurality of memory unit means also being organized into columns;
a write access means allowing a set of data to be written to set of memory unit means in a selected one of the rows; and
a read access means allowing a set of data to be read from a set of memory unit means in a selected one of the columns.

26. A memory comprising:
a plurality of memory units, the plurality of memory units being organized into rows, the plurality of memory units also being organized into columns;
a write access means allowing a set of data to be written to set of memory unit means in a selected one of the rows; and
a read access means allowing a set of data to be read from a set of memory unit means in a selected one of the columns.

27. The memory of claim 26, wherein:
the write access means includes at least an address decoder means; and
the read access means includes at least an address decoder means.

28. The memory of claim 26, wherein:
the write access means includes at least a set of write address lines, each write address line being attached to a set of memory units; and
the read access means includes at least a set of read address lines, each read address line being attached to a set of memory units.

29. A data processing system comprising:
an SRAM; and
a second memory according to claim 1.

30. A data processing system according to claim 29 comprising a data processor.

31. The data processing system of claim 29, wherein the data processor and second memory are disposed on the same chip.

32. The data processing system of claim 29, wherein:
the write access circuit includes at least a set of write address lines, each write address line attached to a set of memory units; and
the read access circuit includes at least a set of read address lines, each read address line attached to a set of memory units.

33. A data processing system comprising:
a memory according to claim 1; and
a data processor, wherein the memory and data processor are disposed on the same chip.

34. The data processing system of claim 33, wherein:
the write access circuit includes at least a set of write address lines, each write address line attached to a set of memory units; and
the read access circuit includes at least a set of read address lines, each read address line attached to a set of memory units.
